(19) United States
(12) Patent Application Publication
(10) Pub. No.: US 2024/0290609 A1
(43) Pub. Date: Aug. 29, 2024

(54) SUBSTRATE PROCESSING METHOD AND SUBSTRATE PROCESSING APPARATUS

(71) Applicant: Tokyo Electron Limited, Minato-ku, Tokyo (JP)

(72) Inventors: Tadahiro ISHIZAKA, Nirasaki City, Yamanashi (JP); Kunihiro TADA, Nirasaki City, Yamanashi (JP); Takashi SAKUMA, Nirasaki City, Yamanashi (JP); Yoshiyuki HANADA, Nirasaki City, Yamanashi (JP)

(21) Appl. No.: 18/572,959

(22) PCT Filed: Jun. 8, 2022
(86) PCT No.: PCT/JP2022/023167

§ 371 Date: Dec. 21, 2023

(30) Foreign Application Priority Data
Jun. 22, 2021 (JP) 2021-103472

(51) Int. Cl. H01L 21/02; C23C 16/02; C23C 16/04; C23C 16/08; C23C 16/42; C23C 16/50; H01J 37/32; H01L 21/285; H01L 21/768

(52) U.S. Cl. CPC H01L 21/02068; C23C 16/0227; C23C 16/045; C23C 16/08; C23C 16/42; C23C 16/50; H01J 37/3244; H01J 37/32733; H01J 37/32816; H01J 37/32899; H01L 21/28518; H01L 21/76877; H01J 2237/3321

(57) ABSTRACT

A substrate processing method includes: a first oxide film removal process of supplying a first processing gas to a substrate, which includes a first metal film and a silicon-containing film, to remove a metal oxide film on a surface of the first metal film; a silicide formation process of supplying a second processing gas to the substrate to for a silicide on a surface of the silicon-containing film; and a film formation process of supplying a film formation gas to the substrate to deposit a second metal film on the first metal film and the silicide, after the first oxide removal process and the silicide formation process.

### TECHNICAL FIELD

The present disclosure relates to a substrate processing method and a substrate processing apparatus.

### BACKGROUND

In manufacturing a semiconductor device, a metal wiring is formed on a semiconductor wafer (hereinafter referred to as a “wafer”), which is a substrate. In a process of forming such a wiring, a process of removing an oxide on a surface of a metal film may be performed. For example, Patent Document 1 discloses a method of removing an oxide on a tungsten film.

### PRIOR ART DOCUMENT

### Patent Document

Patent Document 1: Japanese Patent Laid-Open Publication No. 2020-59916

### SUMMARY

The present disclosure provides a technique capable of forming a wiring with a low resistance value on a substrate.

According to one embodiment of the present disclosure, a substrate processing method includes: a first oxide film removal process of supplying a first processing gas to a substrate, which includes a first metal film and a silicon-containing film, to remove a metal oxide film on a surface of the first metal film; a silicide formation process of supplying a second processing gas to the substrate to silicide a surface of the silicon-containing film; and a film formation process of supplying a film formation gas to the substrate to deposit a second metal film on the first metal film and the metal silicide film, after the first oxide removal process and the silicide formation process.

According to the present disclosure, it is possible to form a wiring with a low resistance value on a substrate.

### BRIEF DESCRIPTION OF DRAWINGS

FIG. 1A is a longitudinal cross-sectional side view of a wafer on which a processing according to an embodiment of the present disclosure is performed.

FIG. 1B is a longitudinal cross-sectional side view of the wafer.

FIG. 1C is a longitudinal cross-sectional side view of the wafer.

FIG. 2A is a longitudinal cross-sectional side view of the wafer.

FIG. 2B is a longitudinal cross-sectional side view of the wafer.

FIG. 2C is a longitudinal cross-sectional side view of the wafer.

FIG. 3 is a chart illustrating a processing flow performed on a wafer A.

FIG. 4 is a plan view illustrating an embodiment of a substrate processing apparatus for performing the processing.

FIG. 5 is a longitudinal cross-sectional side view illustrating an example of a processing module provided in the substrate processing apparatus.

### DETAILED DESCRIPTION

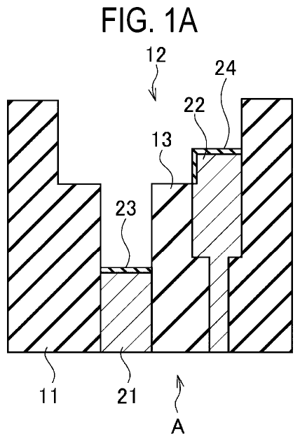

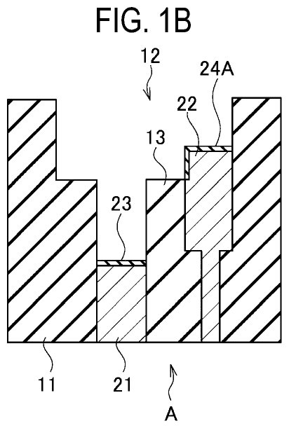

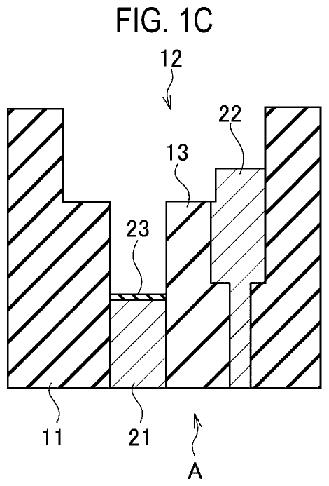

In describing an embodiment of a substrate processing method of the present disclosure, a configuration of a wafer A, which is a substrate before processing, will be described. FIG. 1A is a longitudinal cross-sectional side view illustrating a surface layer of the wafer A before processing. The wafer A is made of, for example, silicon (Si), but a layer made of Si (Si layer) is omitted.

A silicon oxide (SiOₓ) layer 11 is formed on the Si layer. A long vertical hole is formed in the SiOₓ layer 11, and a tungsten (W) film 21 is provided at a lower portion in the hole. A lower portion of the W film 21 is formed to be subsided into the Si layer and has a wiring structure called a buried power rail (BPR), which is aimed at miniaturizing a semiconductor device manufactured from the wafer A.

A recess 12 opened upward is defined by the SiOₓ layer 11 and the W film 21. A sidewall of the recess 12 is defined by the SiOₓ layer 11, and a step 13 is provided in the sidewall of the recess 12 so that an opening width of an upper portion of the sidewall becomes larger than that of a lower portion of the sidewall. The step 13 formed by the SiOₓ layer 11 is provided with a hole extending in a vertical direction (thickness direction of the wafer A), and a Si film 22 is buried in the hole. An upper portion of the Si film 22 slightly protrudes from an upper surface of the step 13. The Si film 22 is configured, for example, as a source or drain of a semiconductor device manufactured from the wafer A, and a lower end thereof is connected to the Si layer.

Since the respective films and layers are configured as described above, a bottom of the recess 12 is constituted by the W film 21, the SiOₓ layer 11 forming the step 13, and the Si film 22. In addition, a surface of the W film 21 and a surface of the Si film 22 facing an interior of the recess 12 are naturally oxidized to form a tungsten oxide (WOₓ) film 23 and a SiOₓ film 24, respectively.

A processing of the wafer A will now be briefly described. A ruthenium (Ru) film 27 is formed as a metal wiring in the recess 12, and is stacked on the W film 21 and the Si film 22 so that the Ru film 27 electrically contacts the W film 21 and the Si film 22. In forming such a contact, a surface layer of the Si film 22 is metal-silicided by titanium (Ti). In addition, before the metal-silicidation and the formation of the Ru film, the WOₓ film 23 and the SiOₓ film 24 are removed.

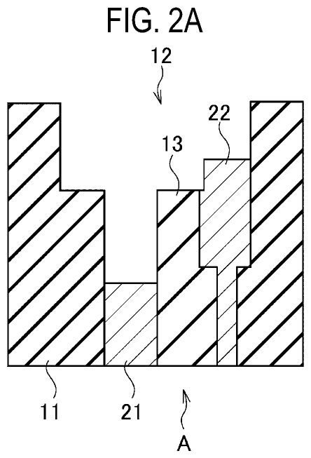

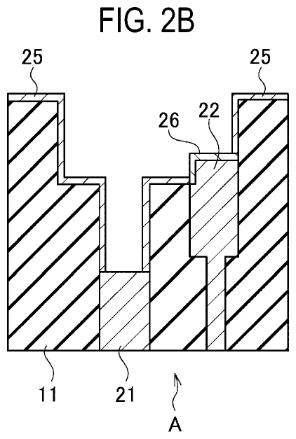

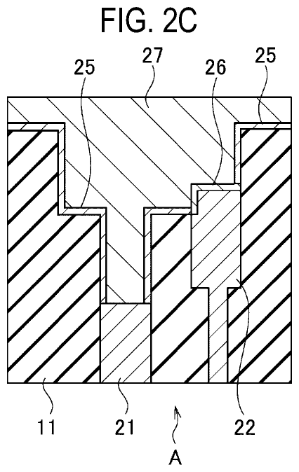

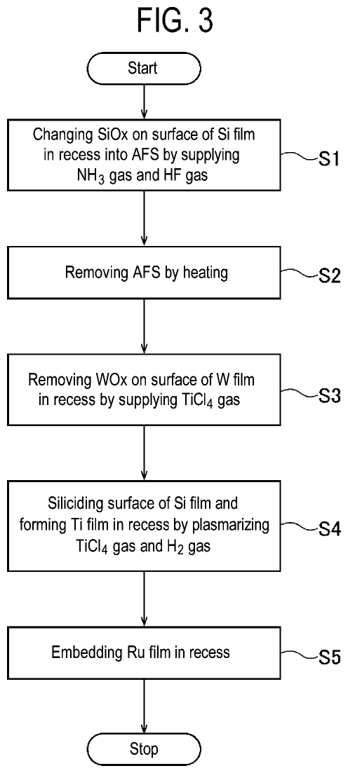

Hereinafter, a series of processes performed on the wafer A will be described with reference to FIGS. 1B, 1C, and FIGS. 2A to 2C, which illustrate changes in a surface of the wafer A. In addition, appropriate reference is also made to a processing flowchart of FIG. 3. During the series of processes illustrated in the flowchart, an environment around the wafer A is kept in a vacuum atmosphere. That is, the wafer A is not exposed to the atmospheric atmosphere during the series of processes. In addition, each of the processes is performed in a state in which the wafer A is stored in a processing container.

First, NH₃ gas and HF gas, which are a third processing gas, are supplied to the wafer A. These gases react with the SiOₓ film 24 to change (modify) the SiOₓ film 24 into an ammonium fluorosilicate (AFS) film 24A (see FIG. 1B, step S1). Subsequently, an inert gas, for example, N₂ gas, is supplied to the wafer A, and the wafer A is heated to a temperature higher than a temperature when step S1 is performed. Thus, the AFS film 24A is sublimated and removed from the surface of the wafer A, and the Si film 22 is exposed in the recess 12 (see FIG. 1C, step S2).

Subsequently, titanium tetrachloride (TiCl₄) gas is supplied to the wafer A as a first processing gas while the wafer A is set to have a temperature of, for example, about 400 degrees C. The WOₓ film 23, which is a metal oxide film, reacts with the TiCl₄ gas to be etched, and the W film 21 is exposed in the recess 12 (see FIG. 2A, step S3). Subsequently, for example, in a state in which the wafer A is set to have the same temperature as the temperature when step S3 is performed, the TiCl₄ gas and H₂ gas, which is a reducing gas for TiCl₄, are supplied to the wafer A as a second processing gas, and are plasmarized to perform plasma chemical vapor deposition (CVD). During this process, TiCl₄ is reduced to generate Ti, and a Ti film 25 serving as a wiring barrier film is formed to cover the SiOₓ layer 11. That is, the Ti film 25, which is a third metal film, is formed to cover the sidewall of the recess 12. In addition, Ti is also deposited on the Si film 22 and reacts with the surface of the Si film 22 by the energy of plasma to form a titanium silicide (TiSiₓ) film 26 as a metal silicide film. That is, the TiSiₓ film 26 is formed to cover the Si film 22 (see FIG. 2B, step S4). Since Ti has a relatively low adsorption property with respect to the W film 21, formation of the Ti film 25 on the W film 21 is suppressed in step S4.

Thereafter, the temperature of the wafer A is set to be a temperature, for example, 200 degrees C. or less, which is lower than the temperature when steps S3 and S4 described above are performed. In addition, Ru₃(CO)₁₂ gas, for example, is supplied as a film formation gas to the wafer A to perform CVD. Thus, the Ru film 27 is formed to be embedded in the recess 12 (see FIG. 2C, step S5). Accordingly, as described above, a contact is formed between the Ru film 27 and the W film 21, and a contact is formed between the Ru film 27 and the Si film 22 via the TiSiₓ film 26 interposed therebetween. In addition, steps S1 and S2 correspond to a second oxide film removal process, step S3 corresponds to a first oxide film removal process, step S4 corresponds to a metal silicide formation process, and step S5 corresponds to a film formation process.

For example, when WOₓ is interposed between the Ru film 27 and the W film 21, a wiring resistance between the Ru film 27 and the W film 21 increases. However, since the WOₓ film 23 is removed in step S3 described above, the wiring resistance may be reduced. In addition, for example, when SiOₓ is interposed between the Ru film 27 and the Si film 22, a wiring resistance between the Ru film 27 and the Si film 22 increases. However, since the SiOₓ film 24 is removed in steps S1 and S2 as described above, the wiring resistance may also be reduced. In addition, since the surface of the Si film 22 is metal-silicided in step S4 and the Si film 22 and the Ru film 27 are connected to each other via the TiSiₓ film 26 in step S5, the wiring resistance between the Si film 22 and the Ru film 27 may be more reliably set to a low value. Accordingly, it is possible to reduce a wiring resistance of a semiconductor device manufactured from the wafer A on which steps S1 to S5 described above are performed.

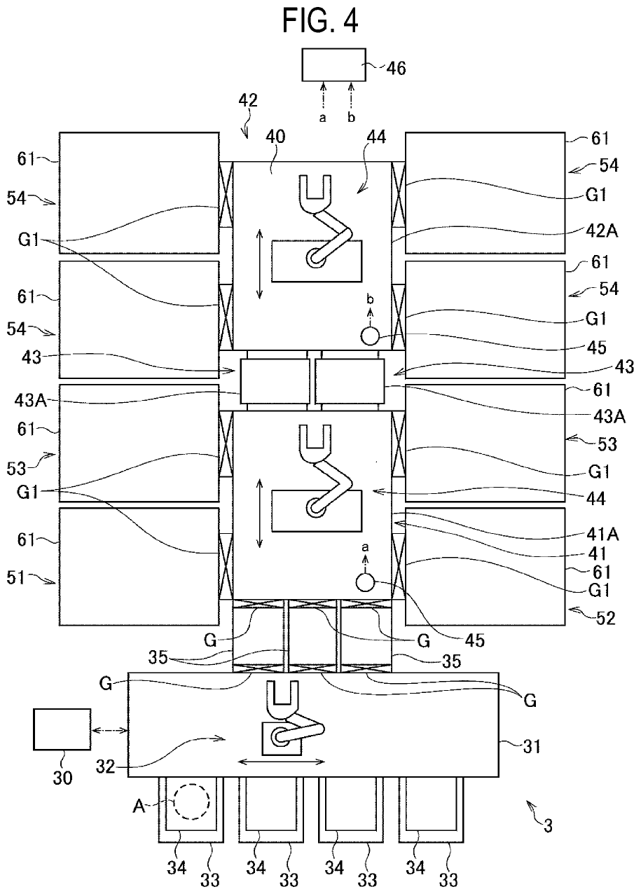

Next, a substrate processing apparatus 3, which is an embodiment of a substrate processing apparatus capable of performing steps S1 to S5, will be described with reference to a plan view of FIG. 4. The substrate processing apparatus 3 includes a loader module 31, load lock modules 35, a first vacuum transfer module 41, a second vacuum transfer module 42, connection modules 43, a first processing module 51, a second processing module 52, third processing modules 53, and fourth processing modules 54. In addition, in the following description, the first vacuum transfer module 41 and the second vacuum transfer module 42 may be collectively described as vacuum transfer modules 41 and 42. In addition, the first to fourth processing modules 51 to 54 may be simply described as processing modules 51 to 54.

The loader module 31, the load lock modules 35, the first vacuum transfer module 41, the connection modules 43, and the second vacuum transfer module 42 are horizontally arranged side by side in a straight line in this order. In the following description of the substrate processing apparatus 3, a side at which the loader module 31 is located is referred to as a front side, and a side at which the second vacuum transfer module 42 is located is referred to as a rear side.

The loader module 31 includes a housing having an interior thereof set to be atmospheric pressure, a transfer mechanism 32 for the wafer A provided in the housing, and load ports 33. In this example, four load ports 33 are arranged side by side on the front side of the housing. A transfer container 34 for storing the wafer A, which is called a front opening unified pod (FOUP), is placed on each load port 33. The transfer mechanism 32 is configured by, for example, an articulated arm capable of moving in a left and right direction, and is capable of transferring the wafer A between the transfer container 34 on each load port 33 and each load lock module 35.

In this example, three load lock modules 35 are arranged side by side in the left and right direction. Each load lock module 35 has a housing, and the housing is connected to the loader module 31 and the first vacuum transfer module 41 via gate valves G provided on the front side and the rear side of the housing, respectively. In addition, in a state in which the gate valves G on the front side and the rear sides of the housing are closed, an internal pressure of the housing can be changed between atmospheric pressure and a vacuum pressure. In addition, a stage (not illustrated) on which the wafer A is placed is provided in the housing, and the stage is configured to be capable of transferring the wafer A with respect to the transfer mechanism 32, which accesses each of the load lock modules 35, and a vacuum transfer mechanism 44, which will be described later.

The first vacuum transfer module 41 and the second vacuum transfer module 42 have the same configuration and include housings 41A and 42A, respectively. An exhaust port 45 is opened in each of the housings 41A and 42A, and one end of an exhaust pipe is connected to the exhaust port 45. The other end of the exhaust pipe is connected to an exhaust mechanism 46 configured by a turbomolecular pump, and interiors of the housing 41A and the housing 42A are maintained to be in a vacuum atmosphere by exhaust from the exhaust port 45 by the exhaust mechanism 46.

In addition, in this example, two connection modules 43 are arranged side by side in the left and right direction. Each connection module 43 has a housing 43A, and the housing 43A is connected to the respective housings 41A and 42A of the vacuum transfer modules 41 and 42. By the exhaust by the exhaust mechanism 46, an interior of the housing 43A of each connection module 43 becomes a vacuum atmosphere having the same pressure as that in the interiors of the housings 41A and 42A. A stage (not illustrated) configured to place the wafer A thereon and deliver the wafer W between the stage and the vacuum transfer mechanism 44, which will be described later, is provided in the housing 43A.

Hereafter, the interior of the housing 41A, the interior of the housing 42A, and the interiors of the housings 43A, which are set to be a vacuum atmosphere by the exhaust mechanism 46, are collectively described as a vacuum transfer path 40 of the wafer A. A further description of the housings 41A and 42A will now be given. Each of the housings 41A and 42A includes a nitrogen (N₂) gas supply, which is not illustrated, and N₂ gas is supplied into each of the housings 41A and 42A. Thus, a pressure in the vacuum transfer path 40 is maintained at a predetermined pressure higher than a pressure inside a processing container constituting each of the processing modules 51 to 54, and an inflow of a gas into the vacuum transfer path 40 is prevented. The exhaust mechanism 46 is configured to be capable of setting, in a state in which the supply of the N₂ gas by the N₂ gas supply is not performed, the pressure of the vacuum transfer path 40 to be lower than 1×10⁻⁷ Torr (1.333×10⁻⁵ Pa). The reason for such a configuration will be described later.

The first processing module 51 and the third processing module 53 are connected to one of a left-hand side and a right-hand side of the housing 41A of the first vacuum transfer module 41 via gate valves G1, and these processing modules 51 and 53 are arranged side by side in a front and rear direction. The second processing module 52 and the third processing module 53 are connected to the other one of the left-hand side and the right-hand side of the housing 41A via the gate valves G1, and these processing modules 52 and 53 are arranged side by side in the front and rear direction. Two fourth processing modules 54 are connected to each of a left-hand side and a right-hand side of the housing 42A of the second vacuum transfer module 42 via the gate valves G. The two third processing modules 53 on each of the left-hand side and the right-hand side of the housing 42A are arranged side by side in the front and rear direction. In addition, the processing modules 51 to 54 may process the wafer A in parallel with one another. Since processing by the fourth processing module 54 requires more time than processing by the other processing modules 51 to 53, in this example, the number of fourth processing modules 54 is the largest among the numbers of the processing modules 51 to 54, thereby improving the throughput.

The vacuum transfer mechanism 44 is provided in each of the housings 41A and 42A and is configured by, for example, an articulated arm capable of moving in the front and rear direction. The vacuum transfer mechanism 44 in the housing 41A delivers the wafer A among the load lock modules 35, the connection modules 43, the first processing module 51, the second processing module 52, and the third processing modules 53. The vacuum transfer mechanism 44 in the housing 42A delivers the wafer A among the connection modules 43 and the fourth processing modules 54.

Correspondence between the processing performed in each of the processing modules 51 to 54 and each step S illustrated in the flow of FIG. 3 is as follows. Step S1 is performed in the first processing module 51, step S2 is performed in the second processing module 52, steps S3 and S4 are performed in the third processing modules 53, and step S5 is performed in the fourth processing modules 54. Each of the processing modules 51 to 54 includes a processing container 61 that is exhausted such that an interior thereof is to be a vacuum atmosphere, and each step S is performed in the processing container 61. Therefore, steps S2 and S3 described above are performed on the wafer A in the same processing container 61. The third processing module 54 constitutes a first processing gas supply and a second processing gas supply, and the processing container 61 of the third processing module 54 corresponds to a first processing container. The processing container 61 of the fourth processing module 54 constituting a film formation gas supply corresponds to a second processing container.

The substrate processing apparatus 3 includes a controller 30, which is a computer, and the controller 30 includes a program. Instructions (respective steps) for processing the wafer A and transferring the wafer A as described above are included in the program. The program is stored in a storage medium, for example, a compact disc, a hard disc, a DVD, and the like, and is installed in the controller 30. The controller 30 outputs control signals to respective components of the substrate processing apparatus 3 according to the program and controls operations of the respective components. Specifically, the controller 30 controls operations of the processing modules 51 to 54, opening and closing of the gate valves G and G1, operations of the transfer mechanism 32, operations of each vacuum transfer mechanism 44, operations of the exhaust mechanism 46, and operations of changing pressures in the load lock modules 35. Specifically, controlling the operations of the processing modules 51 to 54 includes, for example, controlling the temperature of the wafer A by supplying power to a heater 66 to be described later, controlling supply and cut-off of each gas into the processing container 61, and controlling generation of plasma by turning-on and turning-off a radio-frequency power supply 73 with respect to the processing module 53.

A transfer route of the wafer A in the substrate processing apparatus 3 will now be described. The wafer A is first transferred in an order of the transfer container 34→the loader module 31→the load lock module 35→the first vacuum transfer module 41. The wafer A is then transferred in an order of the first processing module 51→the first vacuum transfer module 41→the second processing module 52→the first vacuum transfer module 41→the third processing module 53→the first vacuum transfer module 41→the connection module 43→the second vacuum transfer module 42→the fourth processing module 54. Thereafter, the wafer A is transferred in an order of the second vacuum transfer module 42→the connection module 43→the first vacuum transfer module 41→the load lock module 35→the loader module 31, thereby returning to the transfer container 34.

In addition, the pressure in the housing of the load lock module 35 changes from atmospheric pressure to vacuum when the wafer A is transferred to the first vacuum transfer module 41, and changes from vacuum to atmospheric pressure when the wafer A is transferred to the loader module 31. In addition, after the wafer A is loaded into the first vacuum transfer module 41 as described above, since the wafer A is transferred among the processing containers 61 of the processing modules 51 to 54 via the vacuum transfer path 40 until the wafer A is unloaded from the first vacuum transfer module 41, the wafer A is not exposed to an atmospheric environment while a series of processes of steps S1 to S5 is performed as described above.

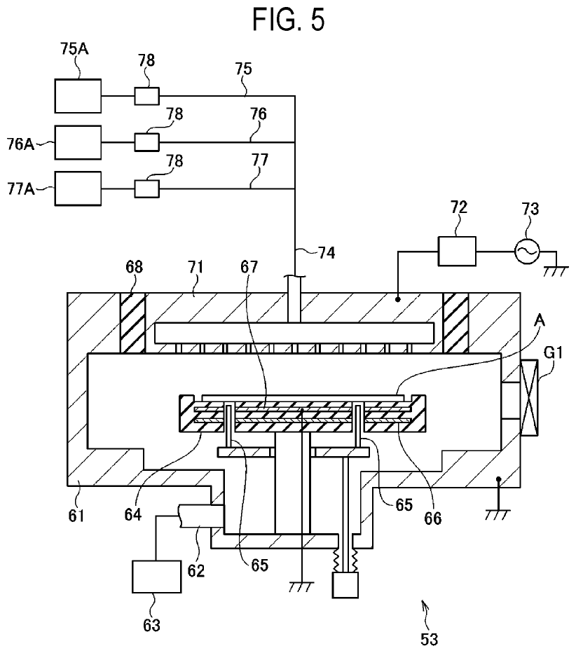

Next, among the processing modules 51 to 54, the third processing module 53 performing steps S3 and S4 will be described as a representative example with reference to a longitudinal cross-sectional side view of FIG. 5. As described above, the third processing module 53 includes the processing container 61, and a transfer port for the wafer A, which is formed on a sidewall of the processing container 61, is opened and closed by the gate valve G1. In addition, the processing container 61 in the third processing module 53 is grounded. In addition, one end of an exhaust pipe 62 is opened on a wall of the processing container 61, and an exhaust mechanism 63 provided at the other end of the exhaust pipe 62 exhausts an interior of the processing container 61 to a vacuum atmosphere of a desired pressure.

A stage 64 on which the wafer A is placed is provided in the processing container 61, and the wafer A is delivered between the stage 64 and the vacuum transfer mechanism 44 by lifting pins 65 configured to be capable of protruding and retracting on the stage 64. The heater 66 is embedded in the stage 64 and heats the wafer A to the above-described temperature during the processing. In addition, an electrode 67 for plasma generation is embedded in the stage 64 and the electrode 67 is grounded.

A gas shower head 71 is provided at a ceiling of the processing container 61 with an insulator 68 interposed therebetween. The gas shower head 71 is connected to the radio-frequency power supply 73 via a matcher 72. The gas shower head 71 and the electrode 67 of the stage 64 are configured as parallel plate electrodes, and plasma may be generated between the gas shower head 71 and the stage 64 by a supply of radio-frequency power from the radio-frequency power supply 73.

A downstream end of a gas supply path 74 is connected to the gas shower head 71. An upstream side of the gas supply path 74 branches to form gas flow paths 75, 76, and 77. An upstream end of the gas flow path 75 is connected to a TiCl₄ gas source 75A, an upstream end of the gas flow path 76 is connected to a H₂ gas source 76A, and an upstream end of the gas flow path 77 is connected to an argon (Ar) gas source 77A. Ar gas is a gas for plasma generation, and serves also as a carrier gas for TiCl₄ gas and H₂ gas.

Gas supply devices 78 each including a valve and a mass flow controller are provided in the gas flow paths 75 to 77 to perform supply and cut-off of respective gases to downstream sides according to control signals from the controller 30. With this configuration, TiCl₄ gas, Ar gas, and H₂ gas may be independently supplied into the processing container 61. In step S3, TiCl₄ gas and Ar gas are supplied into the processing container 61. At this time, the radio-frequency power supply 73 is turned off, and as described above, plasma is not generated in the processing container 61 and the WOₓ film 23 is etched. In addition, in step S4, TiCl₄ gas, Ar gas, and H₂ gas are supplied into the processing container 61. At this time, the radio-frequency power supply 73 is turned on, and as described above, plasma is generated in the processing container 61 and the Ti film 25 and TiSiₓ film 26 are formed.

The processing modules 51, 52, and 54 other than the third processing module 53 will also be briefly described, focusing on differences from the third processing module 53. The processing modules 51, 52, and 54 are not provided with the radio-frequency power source 73 and the electrode 67 of the stage 64, and have a configuration in which plasma is not generated in the processing container 61. A gas source that supplies a gas into the processing container 61 stores a gas according to the processing performed in each processing module. Except for the differences described above, the processing modules 51, 52, and 54 have substantially the same configuration as the third processing module 53. Therefore, while the wafer A placed on the stage 64 is heated to the exemplified temperature in each processing container 61, each exemplified gas is supplied to the wafer A to perform the processing.

However, as described so far, steps S3 and S4 are performed in the third processing module 53, and step S5 is performed in the fourth processing module 54. That is, steps S3 and S4, and step S5 are performed by storing the wafer A in different processing containers 61. This is because, as described above, the processing temperature of the wafer A in steps S3 and S4 is different from the processing temperature of the wafer A in step S5. That is, the apparatus is configured to perform the processing in each processing container 61 as described above, thereby eliminating a need to change the temperature of the stage 64 in each processing container 61 and improving the throughput. In addition, the reason why steps S3 and S4, and step S5 are performed in different processing containers as described above is that a method of cleaning the processing container 61 in steps S3 and S4 using Ti for processing differs from that in step S5 using Ru for processing.

Therefore, as shown in the description of the transfer route of the substrate processing apparatus 3, the wafer A is subjected to a transfer process in which the wafer A is transferred from the processing container 61 of the third processing module 53 to the processing container 61 of the fourth processing module 54 via the vacuum transfer path 40. During the transfer process, when water molecules remain in the vacuum transfer path 40, the surface of the W film 21 is oxidized again by oxygen derived from the water molecules. That is, although the WOₓ film 23 is removed in step S3, the WOₓ film 23 is formed again before the Ru film 27 is formed.

Accordingly, with respect to the substrate processing apparatus 3, after the vacuum transfer path 40 is opened to atmosphere for maintenance and the like, a pressure of the vacuum transfer path 40 is set to be a pressure less than 1×10⁻⁷ Torr by exhaust of the exhaust mechanism 46, so that the water molecules are substantially removed completely from the vacuum transfer path 40. Although removing the water molecules remaining in the vacuum transfer path 40 has been described, respective components leaking into the vacuum transfer path 40 are also removed by the exhaust described above. Thus, each molecule that is a factor in forming the WOₓ film 23, such as oxygen molecules included in the components, is also simultaneously removed. In addition, at this time, N₂ gas is not supplied to the vacuum transfer path 40.

Thereafter, while the exhaust state by the exhaust mechanism 46 (the exhaust state in which the pressure is set to be lower than 1×10⁻⁷ Torr without supplying a gas to the vacuum transfer path 40) is maintained, N₂ gas is supplied to the vacuum transfer path 40 to increase the pressure in the vacuum transfer path 40. Accordingly, an inflow of a gas from the processing container 61 to the vacuum transfer path 40 is prevented as described above. In addition, in a state in which the exhaust and the supply of N₂ gas described above are performed, the wafer A is transferred to the vacuum transfer path 40 and processed by being delivered among the processing modules 51 to 54 in the order described above. As described above, the wafer A is transferred and processed after the vacuum transfer path 40 is set to be a pressure lower than 1×10⁻⁷ Torr, and the vacuum transfer path 40 is operated not to be exposed to atmosphere until the processing for the wafer A is completed.

As described above, the wafer A is transferred from the third processing module 53 to the fourth processing module 54, while passing through the vacuum transfer path 40 in a state in which the water molecules are substantially absent. Thus, the WOₓ film 23 is prevented from being formed again during the transfer. While preventing re-formation of the WOₓ film 23 has been described, since the water molecules in the vacuum transfer path 40 are removed as described above, re-formation of the SiOₓ film 24 is also prevented after the SiOₓ film 24 is removed in steps S1 and S2 and before the Ru film 27 is formed.

In addition, the pressure lower than 1×10⁻⁷ Torr described above is a pressure at which a single layer of oxygen atoms will not adhere to a film when a time required to transfer the wafer A between the processing containers 61 is twenty seconds or less. Therefore, in a case where the wafer A is transferred via the above-described transfer route, when a time required for a transfer from one processing module to a next processing module is twenty seconds or less, it is possible to avoid oxidation of the surface of the wafer W and to keep the surface of the wafer A clean. The transfer operation of the vacuum transfer mechanism 44 may be controlled as described above.

In addition, with respect to step S3, removing the WOₓ film 23 by performing plasma etching may also be considered. However, as described above, the SiOₓ layer 11 is prevented from being damaged by performing etching without generating plasma using a gas consisting of TiCl₄, which is a halide. As a result, it is possible to increase reliability of the wiring of the semiconductor device.

In addition, steps S3 and S4 are performed in the processing container 61 of the same third processing module 53, i.e., in the same processing container 61. Therefore, since a time period from the end of step S3 to the start of step S4 can be shortened, it is possible to improve the throughput of the substrate processing apparatus 3. In addition, by using the processing container 61 commonly as described above, there is an advantage that the configuration of the substrate processing apparatus 3 can be simplified.

In addition, in performing steps S3 and S4 in the common processing container 61, TiCl₄ gas is used in both of steps S3 and S4, whereas different processes are performed on the wafer A according to whether or not plasma is generated and whether or not H₂ gas is supplied. Since TiCl₄ gas is commonly used in steps S3 and S4, a piping system connected to the processing container 61 can be simplified. Thus, there is an advantage that a manufacturing or operating cost of the apparatus can be reduced.

In addition, the WOₓ film 23 can be removed in step S3 by using a gas consisting of a halide other than TiCl₄. As specific examples, BCl₃ gas, WF₆ gas, WCl₅ gas, WCl₆ gas, and the like may be used. Aside therefrom, a halide of Mo or a halide of Ti other than TiCl₄ may also be used. However, since it is desirable to use a gas commonly in steps S3 and S4 as described above, TiCl₄ gas, which is a metal halide, is desirably used in step S3. Even when a gas, such as BCl₃ gas, which is made of a halide different from TiCl₄ gas used in step S4, is used in step S3, steps S3 and S4 can be performed on the wafer A in the same processing container 61. In addition, although it has been described that Ar gas as an inert gas is supplied in step S3, together with the halogen-containing gas, the inert gas is not limited to Ar gas and, for example, N₂ gas may be supplied.

The formation of the Ru film 27 in the recess 12 is not limited to using a film formation gas made of Ru₃(CO)₁₂. For example, a gas containing (2,4-dimethylpentadienyl) (ethylcyclopentadienyl)ruthenium[Ru(DMPD)(EtCp)], bis(2,4-dimethylpentadienyl) ruthenium[Ru(DMPD)₂], (4-dimethylpentadienyl)(methylcyclopentadienyl)ruthenium[(Ru(DMPD)(MeCp)], bis (cyclopentadienyl)ruthenium[(Ru(C₅H₅)₂], cis-dicarbonyl bis(5-methylhexane-2,4-dionate)ruthenium(II), bis(ethylcyclopentadienyl)ruthenium(II)[Ru(EtCp)₂], Ru(chd)(ipmb), Ru(EtBz)(EtCHD), and the like may be used instead of Ru₃(CO)₁₂ to form the Ru film 27.

A second metal film formed in the recess 12 is desirably the Ru film 27 in order to reduce a wiring resistance value, but the second metal film is not limited to the Ru film 27. For example, a molybdenum (Mo) film or a W film, instead of the Ru film 27, may also be desirably formed by supplying a film formation gas to obtain a relatively small wiring resistance value. In addition, although an example of stacking the Ru film 27 on the W film 21, which is a first metal film, has been described, the first metal film is not limited to the W film, and may also be a Ru film or a Mo film exemplified as the second metal film.

In the above example, the silicon-containing film to be metal-silicided is the Si film 22, but the silicon-containing film is not limited to the Si film 22. Specifically, for example, the silicon-containing film may be a silicon germanium (SiGe) film. The silicon-containing film referred to herein means a film composed of silicon itself (i.e., a Si film) or a film composed of a plurality of constituents, such as the SiGe film, one of which is silicon, and does not mean a film containing silicon as an impurity.

The above-described substrate processing apparatus 3 may be configured such that, for example, the first processing module 51 and the second processing module 52 are not provided and steps S1 and S2 are not performed. Specifically, for example, the SiOₓ film 22 may be removed by wet etching outside the substrate processing apparatus 3, and the wafer A may then be transferred to the substrate processing apparatus 3. As described above, in the substrate processing apparatus 3, only the processes after removing the WOₓ film 23 after step S3 may be performed. A further description of setting the pressure of the vacuum transfer path 40 to be lower than 1×10⁻⁷ Torr will now be given. When the apparatus has a configuration of performing only the processes after step S3, it is necessary that the vacuum transfer path 40 reaches a degree of vacuum in the range described above, before the wafer W is transferred to the vacuum path 40 after the removal of the WOₓ film 23 is completed. This prevents the WOₓ film 23 from being re-formed in each stage until the formation of the Ru film 27, after the removal of the WOₓ film 23. When the removal of the SiOₓ film 24 is also performed in the substrate processing apparatus 3, the vacuum transfer path 40 may reach such a degree of vacuum before the wafer W is transferred from the second processing module 52 to the vacuum transfer path 40 after removal of the SiOₓ film 24 is completed. In addition, the vacuum transfer path 40 may reach the degree of vacuum in the range described above at a timing before the wafer W is transferred from the load lock module 35 to the vacuum transfer path 40 as described above.

In addition, in the example illustrated in the flow of FIG. 3, the removal of the WOₓ film 23 in step S3 is performed first, and the formation of the silicide and the formation of the Ti film 25 in step S4 are performed later. However, step S4 may be performed first and step S3 may be performed later. In that case, the Ti film is formed on the WOₓ film 23 in step S4. Thus, since it may take a relatively long time to complete the removal of the WOₓ film 23 in step S3 performed later, it is desirable to perform steps S3 and S4 in this order as illustrated in FIG. 3.

In addition, the embodiments disclosed herein should be considered to be exemplary and not limitative in all respects. The above embodiments may be omitted, replaced, modified, and combined in various ways without departing from the scope and spirit of the appended claims.

### EXPLANATION OF REFERENCE NUMERALS

A: wafer, 21: W film, 22: Si film, 23: WOₓ film, 26: TiSiₓ film, 27: Ru film

1. A substrate processing method, comprising:
a first oxide film removal process of supplying a first processing gas to a substrate, which includes a first metal film and a silicon-containing film, to remove a metal oxide film on a surface of the first metal film;
a metal silicide formation process of supplying a second processing gas to the substrate to form a metal silicide film on a surface of the silicon-containing film; and
a film formation process of supplying a film formation gas to the substrate to deposit a second metal film on the first metal film and the metal silicide film, after the first oxide film removal process and the metal silicide formation process.

2. The substrate processing method of claim 1, wherein the metal silicide formation process is performed after the first oxide film removal process.

3. The substrate processing method of claim 1, further comprising:
before the metal silicide formation process is performed, a second oxide film removal process of supplying a third processing gas to the substrate to modify a silicon oxide film on the surface of the silicon-containing film and heating the substrate to sublimate and remove the modified silicon oxide film.

4. The substrate processing method of claim 1, wherein the first processing gas is a gas containing a halide, and
wherein the first oxide film removal process is performed without plasmarizing the first processing gas.

5. The substrate processing method of claim 4, wherein the first processing gas and the second processing gas are gases containing a same metal halide, and
wherein the metal silicide formation process is performed by plasmarizing the second processing gas.

6. The substrate processing method of claim 5, wherein the metal halide is titanium tetrachloride.

7. The substrate processing method of claim 1, wherein the first metal film and the silicon-containing film constitute a bottom of a recess having a sidewall formed by silicon oxide,
wherein the metal silicide formation process includes a process of forming a third metal film to cover the sidewall of the recess, and
wherein the film formation process is a process of embedding the second metal film in the recess in which the third metal film is formed.

8. The substrate processing method of claim 1, wherein the second metal film is a ruthenium film, a tungsten film, or a molybdenum film.

9. The substrate processing method of claim 1, wherein the first oxide film removal process and the metal silicide formation process are performed on the substrate in a same processing container.

10. The substrate processing method of claim 1, wherein the first oxide film removal process is performed on the substrate in a first processing container having an interior set to be a vacuum atmosphere,
wherein the film formation process is performed on the substrate in a second processing container, which is different from the first processing container and has an interior set to be a vacuum atmosphere, and
wherein the method further comprises:
a transfer process of transferring the substrate from the first processing container to the second processing container via a transfer path of a vacuum atmosphere, after the first oxide film removal process is performed; and
a process of setting a pressure of the transfer path to be lower than 1.333×10⁻⁵ Pa, before the substrate is transferred to the transfer path in the transfer process.

11. A substrate processing apparatus, comprising:
a first processing gas supply configured to supply a first processing gas to a substrate, which includes a first metal film and a silicon-containing film, wherein the first processing gas is for removing a metal oxide on a surface of the first metal film;
a second processing gas supply configured to supply a second processing gas for forming a metal silicide film on a surface of the silicon-containing film to the substrate; and
a film formation gas supply configured to supply a film formation gas to the substrate, to which the first processing gas and the second processing gas are supplied, to deposit a second metal film on the first metal film and the metal silicide film.
